(19) United States
(12) Patent Application Publication
(10) Pub. No.: US 2026/0033335 A1
(43) Pub. Date: Jan. 29, 2026

(54) HIGH ELECTRON MOBILITY TRANSISTOR DEVICE WITH HEAT SPREADER

(71) Applicant: Analog Devices, Inc., Wilmington, MA (US)

(72) Inventors: Justin Scott Reiter, Norwood, MA (US); Marek Hempel, Maldeu, MA (US); Daniel Piedra, Somerville, MA (US); James G. Fiorenza, Carlisle, MA (US)

(21) Appl. No.: 18/781,352

(22) Filed: Jul. 23, 2024

(51) Int. Cl. H01L 23/373; H01L 23/00; H01L 23/14; H01L 23/367; H01L 23/522; H01L 27/085; H01L 29/20; H01L 29/66; H01L 29/778

(52) U.S. Cl. CPC H01L 23/3732; H01L 23/14; H01L 23/367; H01L 23/5226; H10D 30/015; H10D 84/82; H01L 24/32; H01L 2224/32225; H10D 30/475; H10D 62/8503

(57) ABSTRACT

A heat spreader is described that may include a substrate of a top device, and that cools the top die of a flip-chipped die combination. The heat spreader includes a material with a high thermal conductivity, such as a material including diamond. The top heat spreader substrate may have a connection to the bottom base substrate, e.g., carrier.

### FIELD OF THE DISCLOSURE

This document pertains generally, but not by way of limitation, to semiconductor devices, and more particularly, to techniques for constructing gallium nitride devices.

### BACKGROUND

Gallium nitride (GaN) based semiconductors offer several advantages over other semiconductors as the material of choice for fabricating the next generation of transistors, or semiconductor devices, for use in both high-voltage and high-frequency applications. GaN-based semiconductors, for example, have a wide bandgap that enables devices fabricated from these materials to have a high breakdown electric field and to be robust to a wide range of temperatures. The two-dimensional electron gas (2DEG) channels formed by GaN-based heterostructures generally have high electron mobility, making devices fabricated using these structures useful in power-switching and amplification systems.

### SUMMARY OF THE DISCLOSURE

This disclosure describes various techniques to a heat spreader, which may include a substrate of a top device, that cools the top die of a flip-chipped die combination. The heat spreader includes a material with a high thermal conductivity, such as a material including diamond. The top heat spreader substrate may have a connection to the bottom base substrate, e.g., carrier.

In some aspects, this disclosure is directed to a double-sided compound semiconductor heterostructure transistor device, comprising: a first compound semiconductor heterostructure transistor device including: a first substrate including diamond; a first semiconductor material layer formed over the first substrate; a second semiconductor material layer formed over the first semiconductor material layer to form a first compound semiconductor heterostructure having a first two-dimensional electron gas (2DEG) channel, wherein the first 2DEG channel is more conductive than either the first semiconductor material layer or the second semiconductor material layer; and a first cooling layer formed over the second semiconductor material layer of the first compound semiconductor heterostructure transistor device, the first cooling layer including diamond; and a second compound semiconductor heterostructure transistor device formed over the first compound semiconductor heterostructure transistor device, the second compound semiconductor heterostructure transistor device including: a second substrate; a first semiconductor material layer formed over the second substrate; a second semiconductor material layer formed over the first semiconductor material layer to form a second compound semiconductor heterostructure having a second two-dimensional electron gas (2DEG) channel, wherein the second 2DEG channel is more conductive than either the first semiconductor material layer or the second semiconductor material layer; and a second cooling layer formed over the second semiconductor material layer of the second compound semiconductor heterostructure transistor device, the second cooling layer including diamond, wherein the first compound semiconductor heterostructure transistor device and the second compound semiconductor heterostructure transistor device are coupled in a face-to-face arrangement.

In some aspects, this disclosure is directed to a method of forming a double-sided compound semiconductor heterostructure transistor device, the method comprising: forming a first compound semiconductor heterostructure transistor device including: forming a first substrate including diamond; forming a first semiconductor material layer over the first substrate; forming a second semiconductor material layer over the first semiconductor material layer to form a first compound semiconductor heterostructure having a first two-dimensional electron gas (2DEG) channel, wherein the first 2DEG channel is more conductive than either the first semiconductor material layer or the second semiconductor material layer of the first compound semiconductor heterostructure transistor device; and forming a first cooling layer over the second semiconductor material layer of the first compound semiconductor heterostructure transistor device, the first cooling layer including diamond; and forming a second compound semiconductor heterostructure transistor device over the first compound semiconductor heterostructure transistor device in a face-to-face arrangement, the second compound semiconductor heterostructure transistor device including: forming a second substrate; forming a first semiconductor material layer over the second substrate; forming a second semiconductor material layer over the first semiconductor material layer to form a second compound semiconductor heterostructure having a second two-dimensional electron gas (2DEG) channel, wherein the second 2DEG channel is more conductive than either the first semiconductor material layer or the second semiconductor material layer of the second compound semiconductor heterostructure transistor device; and forming a second cooling layer over the second semiconductor material layer of the second compound semiconductor heterostructure transistor device, the second cooling layer including diamond.

In some aspects, this disclosure is directed to a compound semiconductor heterostructure transistor device, comprising: a first compound semiconductor heterostructure transistor device including: a substrate; a first semiconductor material layer formed over the first substrate; a second semiconductor material layer formed over the first semiconductor material layer to form a first compound semiconductor heterostructure having a first two-dimensional electron gas (2DEG) channel, wherein the first 2DEG channel is more conductive than either the first semiconductor material layer or the second semiconductor material layer; a cooling layer formed over the second semiconductor material layer, the cooling layer including diamond; a carrier wafer bonded to the substrate; and a heat spreader coupled with the carrier wafer and enclosing the first compound semiconductor heterostructure transistor device, wherein the heat spreader includes diamond.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 is a cross-sectional view of a double-sided compound semiconductor heterostructure transistor device, in accordance with this disclosure.

FIG. 2 is a cross-sectional view of a single-sided compound semiconductor heterostructure transistor device, in accordance with this disclosure.

FIG. 3 is a flow diagram of an example of a method of forming a double-sided compound semiconductor heterostructure transistor device.

### DETAILED DESCRIPTION

As used in this disclosure, a GaN-based compound semiconductor material may include a chemical compound of elements including GaN and one or more elements from different groups in the periodic table. Such chemical compounds may include a pairing of elements from group 13 (i.e., the group comprising boron (B), aluminum (Al), gallium (Ga), indium (In), and thallium (TI)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons may also be controllably enhanced, such as by an electric field formed by a gate terminal disposed above the channel to control a current through the semiconductor device. Semiconductor devices formed using such conductive channels may include high electron mobility transistor (HEMT) devices.

The present inventors have recognized that thermal management remains a challenge for gallium nitride (GaN) devices. As the power density requirements of the application increase, efficient thermal management becomes even more paramount. The present inventors have recognized that face-to-face bonding may provide a solution to the thermal challenges by reducing the power density per transistor while maintaining or increasing the power density per unit area. This provides an avenue to increase the power density and reduce the parasitic capacitance through hermetic sealing and electric field cancellation. This disclosure describes a heat spreader, which may include a substrate of a top device, that cools the top die of a flip-chipped die combination. The heat spreader includes a material with a high thermal conductivity, such as a material including diamond. The top heat spreader substrate may have a connection to the bottom base substrate, e.g., carrier.

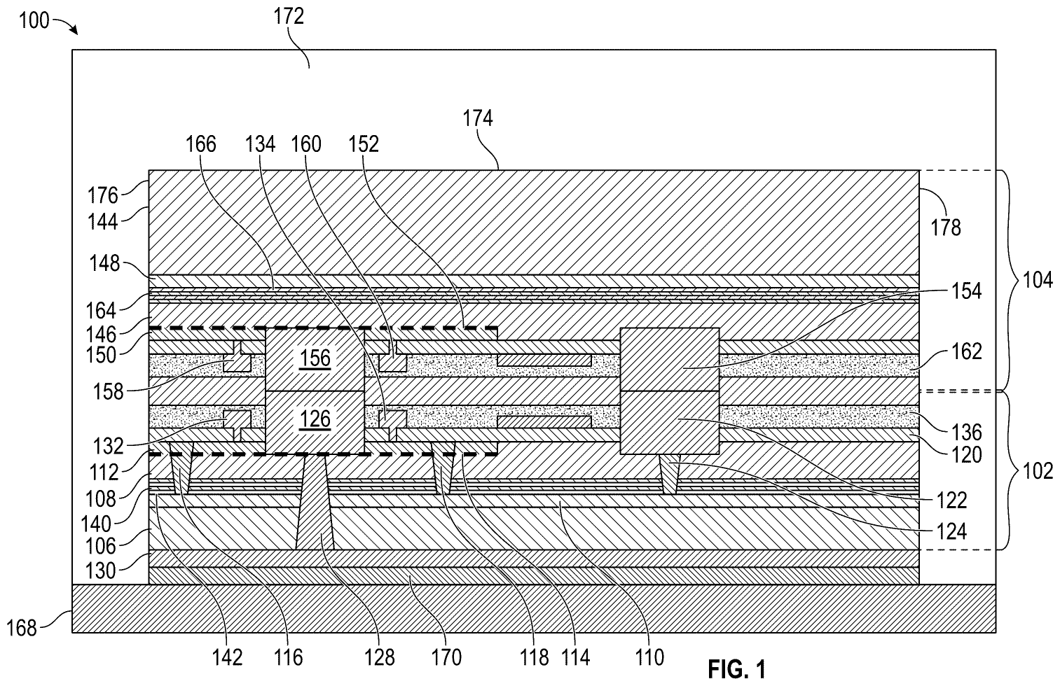

FIG. 1 is a cross-sectional view of a double-sided compound semiconductor heterostructure transistor device 100, in accordance with this disclosure. The double-sided compound semiconductor heterostructure transistor device 100 includes a first compound semiconductor heterostructure transistor device 102 and a second compound semiconductor heterostructure transistor device 104 coupled in a face-to-face arrangement. For example, a top surface (or face) of one device is in contact with the equivalent top surface (or face) of another device. Described another way, in the face-to-face arrangement, the two devices are arranged as mirror images of one another. In some examples, the double-sided compound semiconductor heterostructure transistor device 100 is a high electron mobility transistor (HEMT) device.

The first compound semiconductor heterostructure transistor device 102 includes a substrate 106 and a first semiconductor material layer 108, e.g., GaN, formed over the substrate 106. In some examples, the substrate 106 includes diamond, such as diamond or a diamond composite. Diamond composites include metal-diamond composite, such as copper-diamond or silver-diamond. The substrate 106 may have a thickness greater than 100 micrometers (μm), such as 100 μm to 300 μm. The substrate 106 may be one to ten times (1× to 10×) thicker than silicon (Si) or silicon carbide (SiC) substrates.

In some examples, the first compound semiconductor heterostructure transistor device 102 includes a nucleation layer 110, such as aluminum nitride (AlN), formed between the substrate 106 and the first semiconductor material layer 108. The nucleation layer 110 may provide a transition between the substrate 106 and a GaN layer or aluminum gallium nitride (AlGaN) layer.

A second semiconductor material layer 112 is formed over the first semiconductor material layer 108 to form a first compound semiconductor heterostructure having a first two-dimensional electron gas (2DEG) channel 114 (shown in dashed line). The first 2DEG channel 114 is more conductive than either the first semiconductor material layer 108 or the second semiconductor material layer 112.

A via 116 and a via 118 are shown extending from the second semiconductor material layer 112 to the nucleation layer 110. In some examples, a passivation layer 120, such as silicon nitride (SiN) or silicon oxide, may be formed over the second semiconductor material layer 112.

A drain electrode 122 is formed and coupled with the nucleation layer 110 using a via 124. A source electrode 126 is electrically coupled with the 2DEG channel 114. A via 128 couples the source electrode 126 to a through-substrate via layer 130.

The first compound semiconductor heterostructure transistor device 102 includes one or more gate electrodes, such as a gate electrode 132 and a gate electrode 134, each formed over the second semiconductor material layer 112. The gate electrode 134 is positioned between the source electrode 126 and the drain electrode 122 and also positioned adjacent to a first side of the source electrode 126. The gate electrode 132 is positioned adjacent to a second side of the source electrode 126.

In accordance with this disclosure, the first compound semiconductor heterostructure transistor device 102 further includes a cooling layer 136 formed over the second semiconductor material layer 112, where the cooling layer includes diamond. In some examples, the cooling layer 136 is formed using chemical vapor deposition (CVD). The cooling layer has high thermal conductivity and helps dissipate the heat generated by the first compound semiconductor heterostructure transistor device 102.

In some examples, in addition to the “topside” two-dimensional electron gas (2DEG) channel 114, the first compound semiconductor heterostructure transistor device 102 includes one or more “buried” 2DEG channels toward the bottom of the device, thereby providing multiple 2DEG channels. The buried 2DEG channels are formed by including alternating layers of GaN and AlGaN, for example, where a corresponding 2DEG channel is formed at an interface of those layers. For example, a third semiconductor material layer 140, e.g., AlGaN layer, is formed over a fourth semiconductor material layer 142, e.g., GaN layer, where the fourth semiconductor material layer 142 is formed over the substrate 106, thereby forming a third compound semiconductor heterostructure having a buried 2DEG channel at the interface of the third semiconductor material layer 140 and the fourth semiconductor material layer 142. The buried 2DEG channel is more electrically conductive than either the third semiconductor material layer 140 or the fourth semiconductor material layer 142.

As mentioned above, the double-sided compound semiconductor heterostructure transistor device 100 includes a second compound semiconductor heterostructure transistor device 104 coupled in a face-to-face arrangement with the first compound semiconductor heterostructure transistor device 102. The second compound semiconductor heterostructure transistor device 104 is constructed similarly to the first compound semiconductor heterostructure transistor device 102.

The second compound semiconductor heterostructure transistor device 104 includes a substrate 144 and a first semiconductor material layer 146, such as GaN, formed over the substrate 144. In some examples, the substrate 144 includes diamond, such as diamond or a diamond composite. The substrate 144 may have a thickness of at least 300 μm.

In some examples, the second compound semiconductor heterostructure transistor device 104 includes a nucleation layer 148, such as aluminum nitride (AlN), formed between the substrate 144 and the first semiconductor material layer 146.

A second semiconductor material layer 150 is formed over the first semiconductor material layer 146 to form a second compound semiconductor heterostructure having a two-dimensional electron gas (2DEG) channel 152 (shown in dashed line). The second 2DEG channel 152 is more conductive than either the first semiconductor material layer 146 or the second semiconductor material layer 150.

A drain electrode 154 is formed and coupled with the drain electrode 122 of the first compound semiconductor heterostructure transistor device 102. A source electrode 156 is electrically coupled with the 2DEG channel 152.

The second compound semiconductor heterostructure transistor device 104 includes one or more gate electrodes, such as a gate electrode 158 and a gate electrode 160, each formed over the second semiconductor material layer 150. The gate electrode 160 is positioned between the source electrode 156 and the drain electrode 154 and also positioned adjacent to a first side of the source electrode 156. The gate electrode 158 is positioned adjacent to a second side of the source electrode 156.

The second compound semiconductor heterostructure transistor device 104 further includes a cooling layer 162 formed over the second semiconductor material layer 150, where the cooling layer includes diamond. In some examples, the cooling layer 162 is formed using chemical vapor deposition (CVD). The cooling layer has high thermal conductivity and helps dissipate the heat generated by the second compound semiconductor heterostructure transistor device 104.

In some examples, in addition to the “topside” two-dimensional electron gas (2DEG) channel 114, the first compound semiconductor heterostructure transistor device 102 includes one or more “buried” 2DEG channels, thereby providing multiple 2DEG channels. The buried 2DEG channels are formed by including alternating layers of GaN and AlGaN, for example, where a corresponding 2DEG channel is formed at an interface of those layers. For example, a third semiconductor material layer 164, e.g., AlGaN layer, is formed over a fourth semiconductor material layer 166, e.g., GaN layer, where the fourth semiconductor material layer 166 is formed over the substrate 144, thereby forming a fourth compound semiconductor heterostructure having a buried 2DEG channel at the interface of the third semiconductor material layer 164 and the fourth semiconductor material layer 166. The buried 2DEG channel is more electrically conductive than either the third semiconductor material layer 164 or the fourth semiconductor material layer 166.

The double-sided compound semiconductor heterostructure transistor device 100 of FIG. 1 may be bonded to a carrier wafer or package 168 such as via a bonding polymer 170.

In accordance with this disclosure, the double-sided compound semiconductor heterostructure transistor device 100 may include a heat spreader 172 to spread or distribute heat generated by the device during operation, thereby acting to cool the double-sided compound semiconductor heterostructure transistor device 100. In some examples, the heat spreader includes diamond, such as diamond or diamond composite. Diamond composites may include metal-diamond composites.

The heat spreader 172 encloses the first compound semiconductor heterostructure transistor device 102 and the second compound semiconductor heterostructure transistor device 104 and is coupled to the carrier wafer 168. More particularly, in the face-to-face arrangement, the first compound semiconductor heterostructure transistor device 102 and the second compound semiconductor heterostructure transistor device 104 form three sides: a side 174, which extends along a “top” of the device (“topside”); a side 176, which extends along the left side of the device (“left side”); and a side 178, which extends along the right side of the device (“right side”). As seen in FIG. 1, the heat spreader 172 extends along all three sides so as to enclose the first compound semiconductor heterostructure transistor device 102 and the second compound semiconductor heterostructure transistor device 104. The sidewalls of the top die may or may not make contact to the heat spreader. The carrier wafer 168 extends beyond the side 176 and the side 178 and the heat spreader 172 is formed so as to couple to those extended portions of the carrier wafer 168.

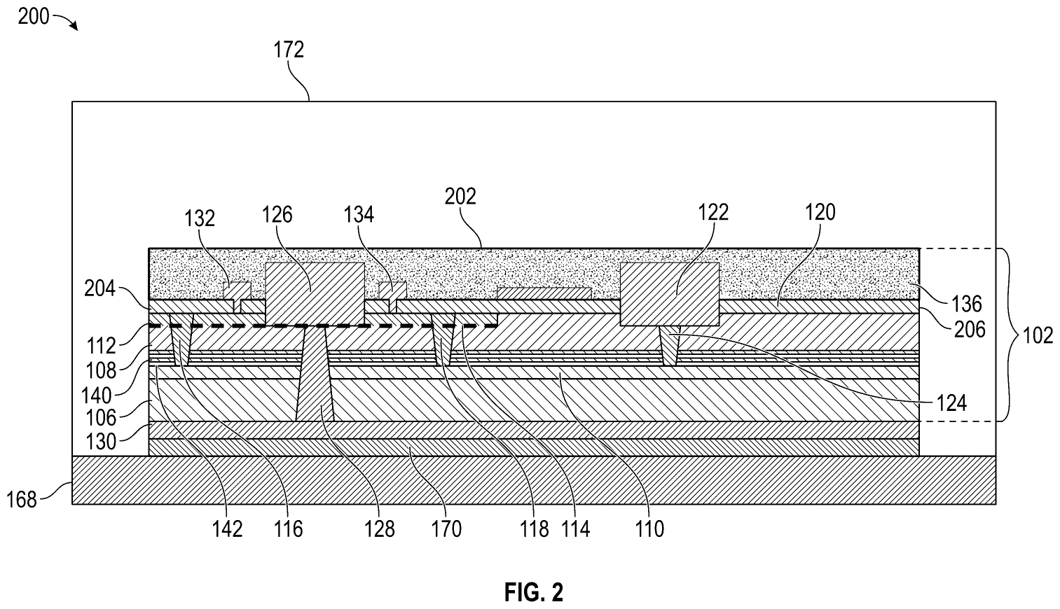

In some examples, the double-sided compound semiconductor heterostructure transistor device 100 of FIG. 1 may include the first compound semiconductor heterostructure transistor device 102 without the second compound semiconductor heterostructure transistor device 104, which is depicted as the compound semiconductor heterostructure transistor device 200 in FIG. 2.

FIG. 2 is a cross-sectional view of a single-sided compound semiconductor heterostructure transistor device 200, in accordance with this disclosure. In some examples, the compound semiconductor heterostructure transistor device 200 is a high electron mobility transistor (HEMT) device. Many of the features of the compound semiconductor heterostructure transistor device 200 are similar to features of the first compound semiconductor heterostructure transistor device 102 of the double-sided compound semiconductor heterostructure transistor device 100 of FIG. 1 and, as such, use similar reference numbers. For purposes of conciseness, similar features will not be described in detail again.

Like in FIG. 1, the compound semiconductor heterostructure transistor device 200 includes a heat spreader 172. The heat spreader 172 is coupled with the carrier wafer 168 and encloses the first compound semiconductor heterostructure transistor device 102. In some examples, the heat spreader 172 includes diamond, such as diamond or a diamond composite. Examples of diamond composites include a metal-composite, such as copper-diamond or silver-diamond.

The first compound semiconductor heterostructure transistor device 102 includes three sides: a side 202, which extends along a “top” of the device (“topside”); a side 204, which extends along the left side of the device (“left side”); and a side 206, which extends along the right side of the device (“right side”).

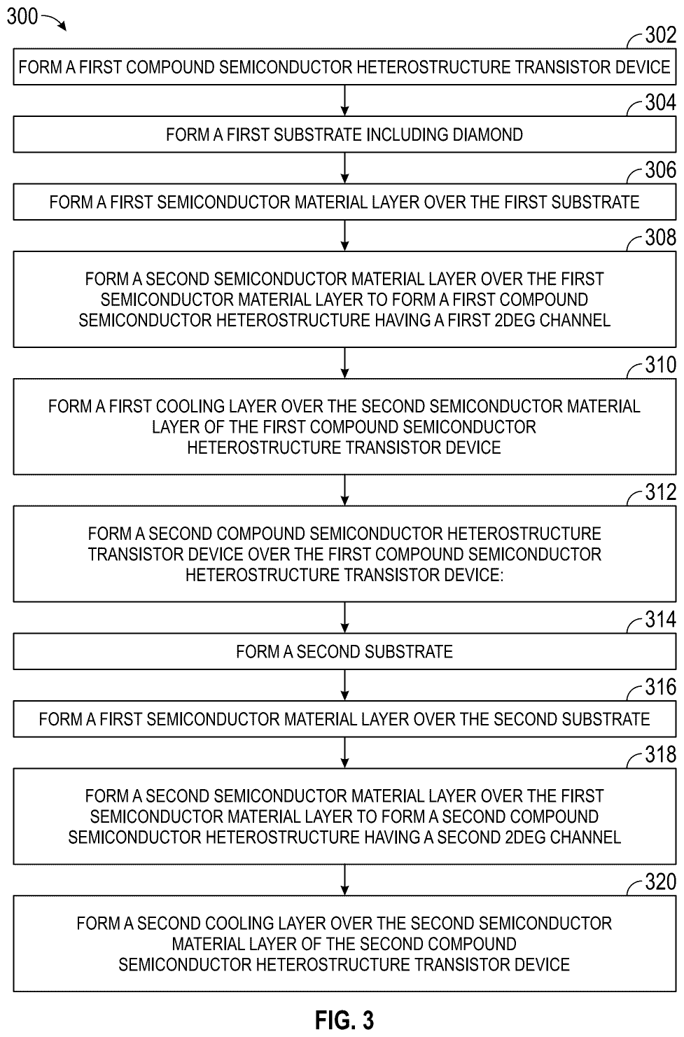

FIG. 3 is a flow diagram of an example of a method 300 of forming a double-sided compound semiconductor heterostructure transistor device. The method 300 describes the process of forming the double-sided compound semiconductor heterostructure transistor device 100 of FIG. 1.

At block 302, the method 300 includes forming a first compound semiconductor heterostructure transistor device, which includes block 304 through block 310. At block 304, the method 300 includes forming a first substrate including diamond. At block 306, the method 300 includes forming a first semiconductor material layer over the first substrate. At block 308, the method 300 includes forming a second semiconductor material layer over the first semiconductor material layer to form a first compound semiconductor heterostructure having a first two-dimensional electron gas (2DEG) channel, where the first 2DEG channel is more conductive than either the first semiconductor material layer or the second semiconductor material layer of the first compound semiconductor heterostructure transistor device.

At block 310, the method 300 includes forming a first cooling layer over the second semiconductor material layer of the first compound semiconductor heterostructure transistor device, the first cooling layer including diamond, such as by using plasma-enhanced chemical vapor deposition (PECVD).

At block 312, the method 300 includes forming a second compound semiconductor heterostructure transistor device over the first compound semiconductor heterostructure transistor device in a face-to-face arrangement, which includes block 314 through block 320. At block 314, the method 300 includes forming a second substrate. In some examples, the second substrate includes diamond or a diamond composite.

At block 316, the method 300 includes forming a first semiconductor material layer over the second substrate. At block 318, the method 300 includes forming a second semiconductor material layer over the first semiconductor material layer to form a second compound semiconductor heterostructure having a second two-dimensional electron gas (2DEG) channel, where the second 2DEG channel is more conductive than either the first semiconductor material layer or the second semiconductor material layer of the second compound semiconductor heterostructure transistor device. At block 320, the method 300 includes forming a second cooling layer over the second semiconductor material layer of the second compound semiconductor heterostructure transistor device, the second cooling layer including diamond.

In some examples, the method 300 includes bonding a carrier wafer to the first substrate. In some examples, the method 300 includes enclosing, using a heat spreader material, the first compound semiconductor heterostructure transistor device and the second compound semiconductor heterostructure transistor device, and coupling the heat spreader material to the carrier wafer.

In some examples, the first 2DEG channel is a topside first 2DEG channel, the second 2DEG channel is a topside second 2DEG channel, and forming the first compound semiconductor heterostructure transistor device further includes forming a third semiconductor material layer over a fourth semiconductor material layer of the first compound semiconductor heterostructure transistor device, where the fourth semiconductor material layer is formed over the first substrate, to form a third compound semiconductor heterostructure having a buried third 2DEG channel, and where the buried third 2DEG channel is more electrically conductive than either the third semiconductor material layer or the fourth semiconductor material layer of the first compound semiconductor heterostructure transistor device.

In some examples, forming the second compound semiconductor heterostructure transistor device further includes forming a third semiconductor material layer formed over a fourth semiconductor material layer of the second compound semiconductor heterostructure transistor device, where the fourth semiconductor material layer is formed over the second substrate, to form a fourth compound semiconductor heterostructure having a buried fourth 2DEG channel, and where the buried fourth 2DEG channel is more electrically conductive than either the third semiconductor material layer or the fourth semiconductor material layer of the second compound semiconductor heterostructure transistor device.

In some examples, the method 300 includes forming the first compound semiconductor heterostructure transistor device 102 without also forming the second compound semiconductor heterostructure transistor device 104, which is depicted as the compound semiconductor heterostructure transistor device 200 in FIG. 2. In those examples, the heat spreader 172 of FIG. 2 is coupled with the carrier wafer 168 and encloses the first compound semiconductor heterostructure transistor device 102. In some examples, the heat spreader 172 includes diamond, such as diamond or a diamond composite. Examples of diamond composites include a metal-composite, such as copper-diamond or silver-diamond.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A double-sided compound semiconductor heterostructure transistor device, comprising:
a first compound semiconductor heterostructure transistor device including:
a first substrate including diamond;
a first semiconductor material layer formed over the first substrate;
a second semiconductor material layer formed over the first semiconductor material layer to form a first compound semiconductor heterostructure having a first two-dimensional electron gas (2DEG) channel, wherein the first 2DEG channel is more conductive than either the first semiconductor material layer or the second semiconductor material layer; and
a first cooling layer formed over the second semiconductor material layer of the first compound semiconductor heterostructure transistor device, the first cooling layer including diamond; and
a second compound semiconductor heterostructure transistor device formed over the first compound semiconductor heterostructure transistor device, the second compound semiconductor heterostructure transistor device including:
a second substrate;
a first semiconductor material layer formed over the second substrate;
a second semiconductor material layer formed over the first semiconductor material layer to form a second compound semiconductor heterostructure having a second two-dimensional electron gas (2DEG) channel, wherein the second 2DEG channel is more conductive than either the first semiconductor material layer or the second semiconductor material layer; and
a second cooling layer formed over the second semiconductor material layer of the second compound semiconductor heterostructure transistor device, the second cooling layer including diamond,
wherein the first compound semiconductor heterostructure transistor device and the second compound semiconductor heterostructure transistor device are coupled in a face-to-face arrangement.

2. The double-sided compound of claim 1, wherein the first compound semiconductor heterostructure transistor device includes:
a first source electrode electrically coupled with the first 2DEG channel; and
a first gate electrode formed over the second semiconductor material layer of the first compound semiconductor heterostructure transistor device, and wherein the second compound semiconductor heterostructure transistor device includes:
a second source electrode electrically coupled with the second 2DEG channel; and
a second gate electrode formed over the second semiconductor material layer of the second compound semiconductor heterostructure transistor device.

3. The double-sided compound of claim 2, wherein the first gate electrode is positioned between the first source electrode and a first drain electrode and positioned adjacent to a first side of the first source electrode, wherein the first compound semiconductor heterostructure transistor device further comprises:
a third gate electrode positioned adjacent to a second side of the first source electrode; and
wherein the second gate electrode is positioned between the second source electrode and a second drain electrode and positioned adjacent to a first side of the second source electrode, wherein the second compound semiconductor heterostructure transistor device further comprises:
a fourth gate electrode positioned adjacent to a second side of the second source electrode.

4. The double-sided compound of claim 1, wherein the first 2DEG channel is a topside first 2DEG channel, wherein the second 2DEG channel is a topside second 2DEG channel, wherein the first compound semiconductor heterostructure transistor device further includes:
a third semiconductor material layer formed over a fourth semiconductor material layer, wherein the fourth semiconductor material layer is formed over the first substrate, to form a third compound semiconductor heterostructure having a buried third 2DEG channel, wherein the buried third 2DEG channel is more electrically conductive than either the third semiconductor material layer or the fourth semiconductor material layer.

5. The double-sided compound of claim 4, wherein the second compound semiconductor heterostructure transistor device further includes:
a third semiconductor material layer formed over a fourth semiconductor material layer, wherein the fourth semiconductor material layer is formed over the second substrate, to form a fourth compound semiconductor heterostructure having a buried fourth 2DEG channel, wherein the buried fourth 2DEG channel is more electrically conductive than either the third semiconductor material layer or the fourth semiconductor material layer.

6. The double-sided compound of claim 1, wherein the first substrate includes a metal-diamond composite.

7. The double-sided compound of claim 1, further comprising:
a carrier wafer bonded to the first substrate.

8. The double-sided compound of claim 7, comprising:
a heat spreader coupled with the carrier wafer and enclosing the first compound semiconductor heterostructure transistor device and the second compound semiconductor heterostructure transistor device.

9. The double-sided compound of claim 8, wherein the heat spreader includes a metal-diamond composite.

10. A method of forming a double-sided compound semiconductor heterostructure transistor device, the method comprising:
forming a first compound semiconductor heterostructure transistor device including:
forming a first substrate including diamond;
forming a first semiconductor material layer over the first substrate;
forming a second semiconductor material layer over the first semiconductor material layer to form a first compound semiconductor heterostructure having a first two-dimensional electron gas (2DEG) channel, wherein the first 2DEG channel is more conductive than either the first semiconductor material layer or the second semiconductor material layer of the first compound semiconductor heterostructure transistor device; and
forming a first cooling layer over the second semiconductor material layer of the first compound semiconductor heterostructure transistor device, the first cooling layer including diamond; and
forming a second compound semiconductor heterostructure transistor device over the first compound semiconductor heterostructure transistor device in a face-to-face arrangement, the second compound semiconductor heterostructure transistor device including:
forming a second substrate;
forming a first semiconductor material layer over the second substrate;
forming a second semiconductor material layer over the first semiconductor material layer to form a second compound semiconductor heterostructure having a second two-dimensional electron gas (2DEG) channel, wherein the second 2DEG channel is more conductive than either the first semiconductor material layer or the second semiconductor material layer of the second compound semiconductor heterostructure transistor device; and
forming a second cooling layer over the second semiconductor material layer of the second compound semiconductor heterostructure transistor device, the second cooling layer including diamond.

11. The method of claim 10, wherein forming a first cooling layer over the second semiconductor material layer of the first compound semiconductor heterostructure transistor device includes:
forming the first cooling layer over the second semiconductor material layer of the first compound semiconductor heterostructure transistor device using chemical vapor deposition (CVD).

12. The method of claim 10, further comprising:
bonding a carrier wafer to the first substrate.

13. The method of claim 12, comprising:
enclosing, using a heat spreader material, the first compound semiconductor heterostructure transistor device and the second compound semiconductor heterostructure transistor device; and
coupling the heat spreader material to the carrier wafer.

14. The method of claim 10, wherein the first 2DEG channel is a topside first 2DEG channel, wherein the second 2DEG channel is a topside second 2DEG channel, and wherein forming the first compound semiconductor heterostructure transistor device further includes:
forming a third semiconductor material layer over a fourth semiconductor material layer of the first compound semiconductor heterostructure transistor device, wherein the fourth semiconductor material layer is formed over the first substrate, to form a third compound semiconductor heterostructure having a buried third 2DEG channel, and wherein the buried third 2DEG channel is more electrically conductive than either the third semiconductor material layer or the fourth semiconductor material layer of the first compound semiconductor heterostructure transistor device.

15. The method of claim 14, wherein forming the second compound semiconductor heterostructure transistor device further includes:
forming a third semiconductor material layer formed over a fourth semiconductor material layer of the second compound semiconductor heterostructure transistor device, wherein the fourth semiconductor material layer is formed over the second substrate, to form a fourth compound semiconductor heterostructure having a buried fourth 2DEG channel, and wherein the buried fourth 2DEG channel is more electrically conductive than either the third semiconductor material layer or the fourth semiconductor material layer of the second compound semiconductor heterostructure transistor device.

16. The method of claim 10, wherein forming the second substrate includes:
forming the second substrate including diamond.

17. A compound semiconductor heterostructure transistor device, comprising:
a first compound semiconductor heterostructure transistor device including:
a substrate;
a first semiconductor material layer formed over the first substrate;
a second semiconductor material layer formed over the first semiconductor material layer to form a first compound semiconductor heterostructure having a first two-dimensional electron gas (2DEG) channel, wherein the first 2DEG channel is more conductive than either the first semiconductor material layer or the second semiconductor material layer;
a cooling layer formed over the second semiconductor material layer, the cooling layer including diamond;
a carrier wafer bonded to the substrate; and
a heat spreader coupled with the carrier wafer and enclosing the first compound semiconductor heterostructure transistor device, wherein the heat spreader includes diamond.

18. The compound semiconductor heterostructure transistor device of claim 17, wherein the substrate includes diamond.

19. The compound semiconductor heterostructure transistor device of claim 17, further comprising:
a second compound semiconductor heterostructure transistor device, wherein the first compound semiconductor heterostructure transistor device and the second compound semiconductor heterostructure transistor device are coupled in a face-to-face arrangement.

20. The compound semiconductor heterostructure transistor device of claim 19, wherein the heat spreader further encloses the second compound semiconductor heterostructure transistor device.
